(19) United States
(12) Patent Application Publication
(10) Pub. No.: US 2010/0220557 A1
(43) Pub. Date: Sep. 2, 2010

(54) BRIDGE OR BOTTOM PLATE FOR A TIMEPIECE MOVEMENT

(75) Inventors: Nakis KARAPATIS, Premier (CH); Fabien Henriet, Delemont (CH); Lucien Germond, Grandson (CH)

Correspondence Address: SUGHRUE MION, PLLC, 2100 PENNSYLVANIA AVENUE, N.W., SUITE 800, WASHINGTON, DC, 20037, US

(73) Assignee: Montres Breguet S.A., L'Abbaye (CH)

(21) Appl. No.: 12/714,956

(22) Filed: Mar. 1, 2010

(30) Foreign Application Priority Data
Mar. 2, 2009 (EP) 09154100

(51) Int. Cl. G04B 29/02; C23C 14/34; C25F 3/02

(52) U.S. Cl. 368/88; 204/192.34; 205/661

(57) ABSTRACT

The invention relates to a timepiece movement that includes at least one bridge (1) mounted on a bottom plate using at least one securing device (2, 4, 6) to carry at least one member of said movement. According to the invention, said at least one bridge or the bottom plate is made from a plate of micromachinable material and includes at least one bearing formed in a single-piece to carry at least one member of said movement.

The invention concerns a bridge or bottom plate made of micromachinable material that comprises a single-piece bearing for use in manufacturing a timepiece movement.

### BACKGROUND OF THE INVENTION

It is known to make bridges of metal such as brass to support the rotations of at least one pivot of a timepiece movement wheel set, while the bottom plate carries the other pivot of said wheel set. The pivots are generally carried in bearings that are added into the bridges and bottom plate. The bearings usually used comprise at least one ruby, also called a jewel, which is used for its very good tribological properties.

In some timepiece movements, the thinness of the case requires making bridges and/or a bottom plate of very small thickness. The top plate of the bridges and/or the bottom plate, i.e. the thinnest part, then becomes very difficult to machine and to work. Indeed, when the machining tool or driving tool for the jewel is applied, axial runout may occur and cause a loss in the flatness and the positioning precision of said elements.

### SUMMARY OF THE INVENTION

It is an object of the present invention to overcome all or part of the aforecited drawbacks by proposing a bridge or bottom plate that includes a single-piece bearing for a timepiece movement whose flatness and precision are improved despite its small thickness.

The invention thus relates to a timepiece movement that includes at least one bridge mounted on a bottom plate using at least one securing device, characterized in that said at least one bridge or the bottom plate is made from a plate of micromachinable material and in that said at least one bridge or the bottom plate includes at least one bearing integral with said at least one bridge so as to carry at least one member of said movement. This advantageously provides an extremely precise single-piece member and avoids the drawbacks caused by assembly steps.

According to other advantageous features of the invention:
said at least one bearing has a jewel-hole made by etching which omits the need for a dedicated jewelling;
the wall of said jewel-hole has a coating for improving its tribological properties compared to said micromachinable material;
said jewel-hole has at least one olive-cut or at least one oil-sink for reducing friction;
the micromachinable material is silicon-based.

The invention also relates to a timepiece, characterized in that it includes a timepiece movement in accordance with one of the preceding variants.

Finally, the invention relates to a method of manufacturing a bearing in a micromachinable element, characterized in that it includes step a) of making an etch so as to form the jewel-hole of said bearing.

According to other advantageous features of the invention:
the etch is performed by anisotropic deep reactive ion etching;
after step a), the method also includes step b): performing a second etch so as to form an olive-cut coaxially to said hole;
after step a), the method also includes step b′): making a second etch so as to form an oil-sink coaxially to said hole;
the second etch is performed by isotropic deep reactive ion etching;
the second etch is performed by a series of anisotropic reactive ion etches whose etch section is gradually reduced;
the second etch is performed by electroerosion;
the method also includes the final step c): forming a coating on the wall of said jewel-hole with a better friction coefficient than said micromachinable element;
step c) includes phase d): performing a physical or chemical phase deposition of a material of better tribological quality than said micromachinable material;
the micromachinable element is silicon-based;
step c) includes phase e): oxidising said silicon-based material so as to form said coating of better tribological quality.

### BRIEF DESCRIPTION OF THE DRAWINGS

Other features and advantages will appear clearly from the following description, given by way of non-limiting illustration, with reference to the annexed drawings, in which:

FIG. 1 is a top perspective view of a bridge according to the invention;

FIG. 2 is a bottom perspective view of a bridge according to the invention;

FIG. 3 is a top view of a bridge according to the invention;

FIG. 4 is a diagram along cross-section A-A of FIG. 3;

FIG. 5 is a flow chart of the method of the invention.

### DETAILED DESCRIPTION OF THE PREFERRED EMBODIMENTS

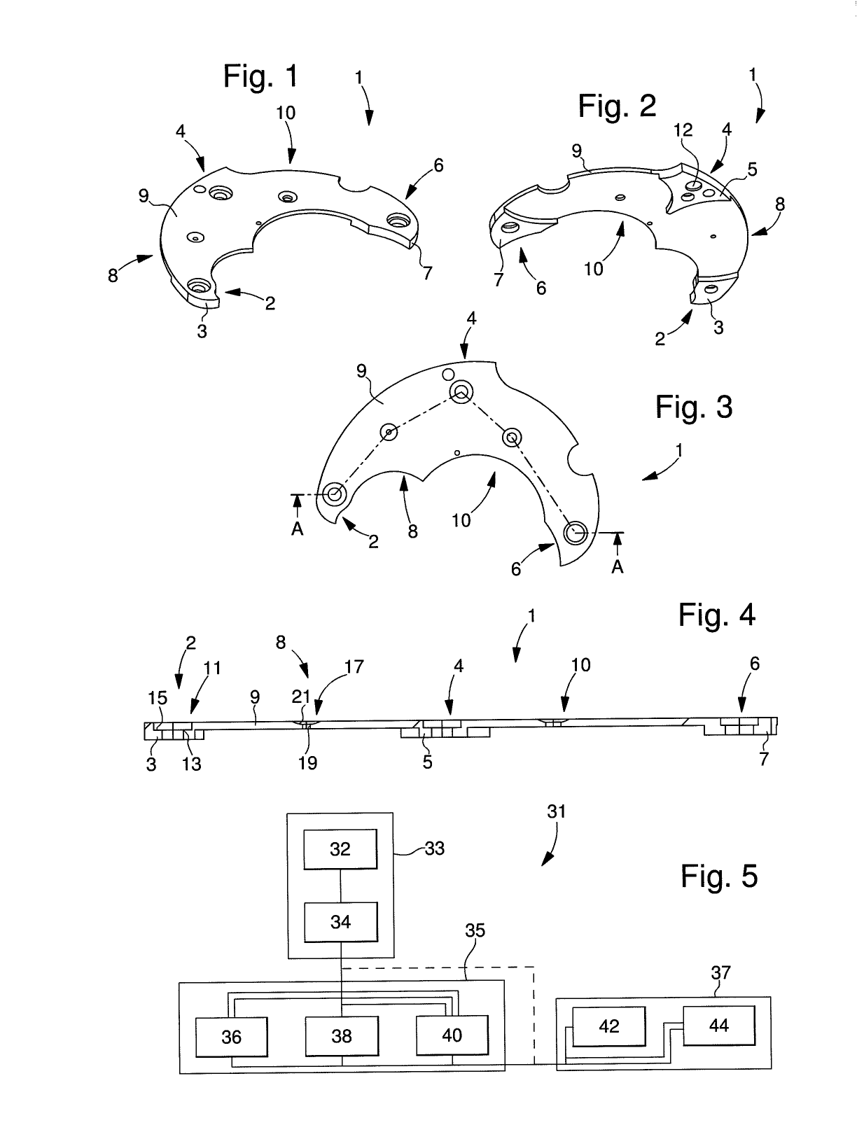

As illustrated in FIGS. 1 to 4, the element chosen to explain the invention is a timepiece movement bridge, generally designated 1, and intended for use in a timepiece. However, it is clear that the invention is also applicable to the bottom plate of a timepiece movement or the plate of said movement that includes the aforecited bridge.

Bridge 1 has three bases 3, 5, 7 above which the plate 9 of said bridge extends. Preferably, the three bases 3, 5, 7 and the plate 9 are single-piece parts. In the example illustrated in FIG. 3, it can be seen that plate 9 has the general shape of a crescent of the moon.

Advantageously, bridge 1 is made from a plate of micromachinable material offering improved precision and flatness. This micromachinable material may be silicon, crystallised silicon or crystallised alumina based. In fact, micromachining a plate whose surfaces are already flat, such as for example a silicon wafer, guarantees very good dimension to be obtained.

Moreover, working precision of the micromachinable material is obtained via a process that uses a dry or wet etch, which avoids the application of local force to remove material. These processes are widely used, particularly for etching calculators and processors in microelectronics, and guarantee etch precision of less than a micrometer. Preferably, a deep reactive ion (DRIE) type etch is used.

One of the known processes consists, first of all, in coating a protective mask on the surface of the micromachinable plate, for example, using a photosensitive resin photolithographic method. In a second phase, the mask-plate assembly is subjected to a DRIE type etch, with only the unprotected parts of the plate being etched. Finally, in a third phase, the protective mask is removed. It is thus clear that the protective mask directly determines the final shape of the elements etched on the plate. It is therefore possible to make any shape in a precise manner.

Consequently, owing to the use of a micromachinable material, the blank of bridge 1 and/or the bottom plate, even if it is of very small thickness, i.e. around 0.4 mm, provides very precise dimensions with very good mechanical properties. It is thus clear, in the example illustrated in FIGS. 1 to 4, that the blank may be obtained, first of all, by an overall etch of the crescent of the moon shape, then, in a second phase, by selectively removing one part of the thickness so as to distinguish one thickness for bases 3, 5, 7 and a smaller thickness for plate 9.

Advantageously, it is also possible with the blank to make recesses over the top part of plate 9 in order to improve the aesthetic effect of said movement. Indeed, for example, numbers, a mark and/or decorations can also be precisely etched in all or part of the thickness of the element.

Preferably, in the example illustrated in FIGS. 1 to 4, the manufactured element is a bridge 1, which has three securing devices 2, 4, 6 for securing bridge 1 to a bottom plate (not shown) by screws. Thus, each securing device 2, 4, 6 has a hole 11 in bridge 1 and, in a known manner, a screw (not shown) that cooperates in rotation with a threaded recess (not shown) in the bottom plate. Obtained using a photolithographic and DRIE process, hole 11 in bridge 1 has two distinct sections forming a shoulder 13 that acts as a stop member for the screw head, enabling bridge 1 to be held against the bottom plate after the screws have been screwed in.

Preferably, shoulder 13 has a coating 15 for receiving the tightening force of said screw head. For example, silicon has virtually no plastic deformation domain. Thus, silicon breaks quickly if an induced stress exceeds its elasticity limit. Preferably, therefore, coating 15 is used, which includes a ductile material for each securing device 2, 4, 6 to avoid damaging bridge 1.

Preferably, coating 15 may include, in a non-limiting manner, gold, copper, nickel or NiP, TiW, AuCr alloys. It may be formed on shoulder 13, for example, by vapour phase deposition, such as cathodic sputtering, along a thickness, for example, of at least 5 micrometers.

Each securing device 2, 4, 6 may also include a foot-recess assembly between said at least one bridge and said bottom plate in order to position these two elements correctly before they are secured. In the example illustrated in FIG. 2, it can be seen that securing device 4 has a blind recess, 12 for cooperating with a foot of the bottom plate.

Preferably, in the example illustrated in FIGS. 1 to 4, bridge 1 also includes two bearings 8, 10 for carrying two distinct pivots of at least one member of said timepiece movement. It is clear that these bearings 8, 10 are also applicable to the bottom plate of a timepiece movement or to the plate of said movement that includes the aforecited bridge 1.

Advantageously, according to the invention, each bearing 8, 10 is made integral with bridge 1, i.e. without the use of any jewelling. Each bearing 8, 10 thus has a jewel-hole 17, i.e. its wall 19 is used as a sliding surface for the rotation of said member pivots.

Preferably, if the tribological properties of the material used are not very good, wall 19 of hole 17 has a coating for reducing the friction coefficient thereby reducing friction with its associated pivot. As explained below, this coating may include silicon dioxide, a nickel and phosphorus based alloy or a diamond like carbon (DLC).

Moreover, hole 17 preferably has an olive-cut and/or an oil-sink 21, at least on the top part thereof, which is for reducing surface friction with said member pivot while facilitating lubrication thereof. Indeed, as visible in FIGS. 1, 3 and 4, the section of oil-sink 21, which is approximately conical in shape, gradually increases from that of hole 17. It is thus clear that the member pivot rotates while sliding against a smaller surface, which reduces friction. It is also clear that oil-sink 21 allows easy lubrication of said pivot, which is likely to further reduce said friction.

The method 31 of manufacturing an element like a bridge 1 and/or a bottom plate will now be explained with reference to FIG. 5. Method 31 mainly includes a step 33 of forming holes, a step 35 of forming olive-cuts and/or oil-sinks and a step 37 of forming coatings.

The first step 33 is for forming the holes 11 of each securing device 2, 4, 6 and/or the holes 17 of each bearing 8, 10. In a first phase 32, a blank of bridge 1 is taken, as explained above. Then, during phase 34, the holes 11 and/or 17 are etched using a process that includes photolithography and anisotropic DRIE methods.

Preferably, in the case of holes 11, a dual protective mask method is used to form shoulders 13. Thus, two masks are structured, with one overlapping the other, wherein the unprotected section of the second mask is smaller than that of the first mask. This means that phase 34 can start by etching only the smallest section. At a predetermined etch depth, phase 34 is interrupted, in order to remove the second mask. Etch phase 34 is then resumed to continue etching the small section and start etching the large section at the same time, up to the desired depth, i.e. to make the small section of hole 11 open out into the large section.

Step 35 is for forming the olive-cuts and/or oil-sinks 21 at least at one end of each hole 17 of bearing 8, 10. As visible in FIG. 5, the invention includes three embodiments respectively represented by double, single and triple lines.

In a first embodiment visible in double lines in FIG. 5, step 35 includes a phase 36 in which oils sinks 21 are etched using a process that includes photolithography and isotropic DRIE methods. Indeed, an isotropic etch can etch approximately in the shape of a half-sphere allowing said oil-sink to be made in a conical shape.

In a second embodiment, visible in a single line in FIG. 5, step 35 includes a phase 38, in which oils sinks 21 are etched using a process that includes photolithography and anisotropic DRIE methods, wherein the etch section is gradually reduced by altering the unprotected sections of the protective masks. This embodiment forms an oil-sink 21 approximately in the shape of steps, and is, for this reason, preferably followed by oxidation so as to flatten said steps.

In a third embodiment visible in triple lines in FIG. 5, step 35 includes a phase 40 in which oil-sinks 21 are etched using an electroerosion process. Preferably, the electroerosion is performed with a conical electrode so as to form said conical pattern cavity for oil-sink 21. Preferably, in order to improve the quality of phase 40, the element includes a strongly doped silicon-based material to increase its electrical conductivity.

After step 35 or after step 33, as shown in dotted lines in FIG. 5, method 31 may also include step 37 for forming low friction coefficient coatings on wall 19 of holes 17 of bearing 8, 10.

A first variant of step 37 shown in a single line may include a phase 42 for performing a physical or chemical vapour or liquid phase deposition of a material of better tribological quality than said micromachinable material. This material may be, for example, a nickel and phosphorus based alloy or a diamond like carbon (DLC).

A second variant of step 37 shown in double lines may include a phase 44 for oxidising said silicon-based material to form a silicon dioxide coating of better tribological quality.

In an alternative to step 37, after step 33 as shown in dotted lines in FIG. 5, method 31 may also include step 37 for forming ductile coatings 15 for shoulders 13 of securing devices 2, 4, 6. Step 37 may then include a phase 42 for performing physical or chemical vapour or liquid phase deposition of a ductile material. This material may be, for example, gold, copper, nickel or NiP, TiW, AuCr alloys.

Of course, the present invention is not limited to the illustrated example, but is capable of various variants and alterations, which will be clear to those skilled in the art. In particular, a final oxidisation step may be performed to form a silicon dioxide layer for mechanically reinforcing bridge 1 and/or the bottom plate made of silicon-based material. Moreover, the securing devices 2, 4, 6 shown use screwing means, however, they are not limited to such means. The screws may be replaced by means for driving in, bonding or tightening.

What is claimed is:

1. A method of manufacturing a bearing in a silicon-based element, wherein it includes the following steps:
a) performing a first etch so as to form the jewel-hole for said bearing,
b) performing a second etch so as to form an olive-cut or an oil-sink coaxially to said hole.

2. The method according to claim 1, wherein the first etch is performed by anisotropic deep reactive ion etching.

3. The method according to claim 1, wherein the second etch is performed by isotropic deep reactive ion etching.

4. The method according to claim 1, wherein the second etch is performed by a series of anisotropic deep reactive ion etches whose etch section is gradually reduced.

5. The method according to claim 4, wherein step b) is followed by the following step:
c) oxidising said silicon-based element so as to flatten said second etch.

6. The method according to claim 1, wherein the second etch is performed by electroerosion.

7. The method according to claim 6, wherein the element is doped silicon-based to improve the electroerosion quality.

8. A timepiece movement including at least one bridge mounted on a bottom plate using at least one securing device, said at least one bridge or said bottom plate is made from a plate made of silicon-based material and includes at least one bearing formed in a single-piece by a jewel-hole to carry at least one member of said movement without any dedicated jewelling, wherein said hole has an approximately cone-shaped part so as to reduce friction.

9. The timepiece movement according to claim 8, wherein said approximately cone-shaped part forms an olive-cut.

10. The timepiece movement according to claim 8, wherein said approximately cone-shaped part forms an oil-sink, which also facilitates lubrication.
